(19) United States
(12) Patent Application Publication
(10) Pub. No.: US 2025/0298253 A1
(43) Pub. Date: Sep. 25, 2025

(54) HEAD-MOUNTED DISPLAY DEVICE

(71) Applicant: Coretronic Corporation, Hsin-Chu (TW)

(72) Inventors: Wei-Min Chien, Hsin-Chu (TW); Tung-Chou Hu, Hsin-Chu (TW)

(73) Assignee: Coretronic Corporation, Hsin-Chu (TW)

(21) Appl. No.: 19/063,305

(22) Filed: Feb. 26, 2025

(30) Foreign Application Priority Data
Mar. 20, 2024 (CN) 202410318180.1

(51) Int. Cl. G02B 27/01

(52) U.S. Cl. CPC G02B 27/0176; G02B 27/0172

(57) ABSTRACT

A head-mounted display device includes a housing, an optical engine module, and a heat dissipating module. The housing has a display portion and a support portion. The display portion has a first space. The support portion has a second space communicated with the first space. The support portion has a side wall and a heat dissipating wall. A material of the heat dissipating wall is an infrared transmitting material and different from a material of the side wall. The optical engine module includes a heat source and is disposed in the first space. A part of the heat dissipating module is disposed in the first space and connected to the heat source. Another part of the heat dissipating module is disposed in the second space. Heat generated by the heat source is transferred to the heat dissipating module and transferred to an outside of the housing by radiation.

### CROSS-REFERENCE TO RELATED APPLICATION

This application claims the priority benefit of China application serial no. 202410318180.1, filed on Mar. 20, 2024. The entirety of the above-mentioned patent application is hereby incorporated by reference herein and made a part of this specification.

### BACKGROUND

### Technical Field

The disclosure relates to a display device, and in particular to a head-mounted display device.

### DESCRIPTION OF RELATED ART

As the technology industry becomes increasingly developed, the forms, functions, and usage manners of display devices are becoming more and more diverse, and the wearable display device that may be directly worn on the body of a user has also emerged accordingly. Currently, the wearable display device may have a display module, a processing module such as a system on a chip (SoC), and a network module, and the modules generate heat. Since the wearable display device is in direct contact with the user, if active heat dissipation (for example, a fan) that generates vibration and noise is adopted, the experience of the user will be greatly affected. However, if a passive heat dissipating element is adopted to dissipate heat from a heat source, the heat dissipating ability of the wearable display device will be significantly limited. In addition, there are strict surface temperature regulations in terms of safety regulations for the wearable display device. The surface temperature thereof cannot exceed 48° C. Moreover, since the wearable display device is directly worn on the body of the user, the weight and the size are limited, so the modules that generate heat cannot have sufficient heat dissipation areas, which also significantly limits the heat dissipating ability of the wearable display device.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

The disclosure provides a head-mounted display device, which improves heat dissipation efficiency.

Other objectives and advantages of the disclosure may be further understood from the technical features disclosed in the disclosure.

In order to achieve one, a part, or all of the above objectives or other objectives, an embodiment of the disclosure provides a head-mounted display device, including a housing, an optical engine module, and a heat dissipating module. The housing has a display portion and a support portion. The display portion has a first space, the support portion has a second space, and the first space and the second space are communicated. The support portion has a side wall and at least one heat dissipating wall, and a material of the at least one heat dissipating wall is an infrared transmitting material and is different from a material of the side wall. The optical engine module includes at least one heat source and is disposed in the first space. A part of the heat dissipating module is disposed in the first space and is connected to the at least one heat source. Another part of the heat dissipating module is disposed in the second space. Heat generated by the at least one heat source is transferred to the heat dissipating module and is transferred from the at least one heat dissipating wall to an outside of the housing by radiation.

Based on the above, the embodiments of the disclosure have at least one of the following advantages or effects. In the design of the head-mounted display device of the disclosure, the material of the heat dissipating wall of the support portion is the infrared transmitting material and is different from the material of the side wall of the support portion. The heat generated by the heat source is transferred to the heat dissipating module and is transferred from the heat dissipating wall to the outside of the housing by radiation, so as to increase a radiation heat dissipation area, so that the head-mounted display device of the disclosure has improved heat dissipation and display quality.

Other objectives, features and advantages of the disclosure will be further understood from the further technological features disclosed by the embodiments of the disclosure wherein there are shown and described preferred embodiments of this invention, simply by way of illustration of modes best suited to carry out the invention.

### BRIEF DESCRIPTION OF THE DRAWINGS

FIG. 1A is a three-dimensional schematic view of a head-mounted display device worn on a user according to an embodiment of the disclosure.

FIG. 1B is a partial top perspective schematic view of the head-mounted display device of FIG. 1A.

FIG. 1C is a partial front perspective schematic view of the head-mounted display device of FIG. 1A.

FIG. 1D is a side perspective schematic view of the head-mounted display device of FIG. 1A.

FIG. 1E is a cross-sectional schematic view along a line I-I of FIG. 1D.

FIG. 1F is a three-dimensional schematic view of a heat dissipating module of FIG. 1D.

FIG. 1G is a detailed schematic view of an optical engine module in FIG. 1D.

FIG. 2A is a partial top perspective schematic view of a head-mounted display device according to another embodiment of the disclosure.

FIG. 2B is a partial front perspective schematic view of the head-mounted display device of FIG. 2A.

FIG. 2C is a side perspective schematic view of the head-mounted display device of FIG. 2A.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top”, “bottom”, “front”, “back”, etc., is used with reference to the orientation of the Figure(s) being described. The components of the disclosure can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the disclosure. Also, it is to be understood that the phraseology and terminology used herein are for the purpose of description and should not be regarded as limiting. The use of “including”, “comprising”, or “having” and variations thereof herein is meant to encompass the items listed thereafter and equivalents thereof as well as additional items. Unless limited otherwise, the terms “connected”, “coupled”, and “mounted” and variations thereof herein are used broadly and encompass direct and indirect connections, couplings, and mountings. Similarly, the terms “facing”, “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

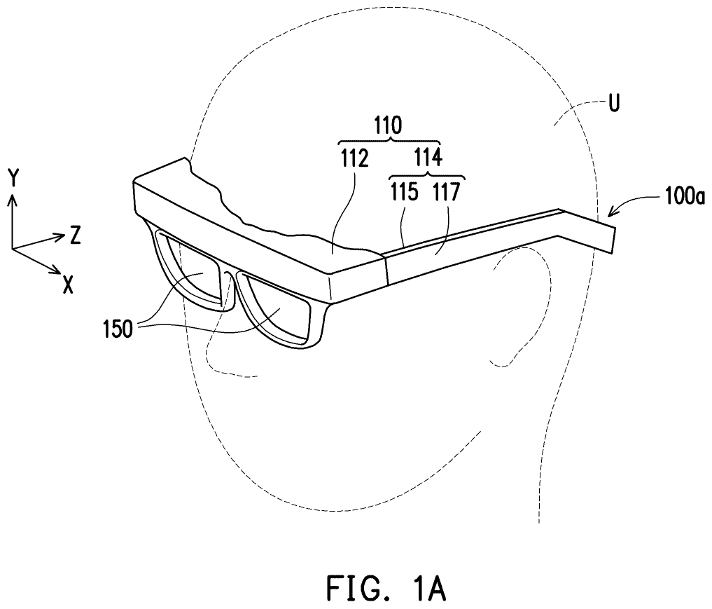

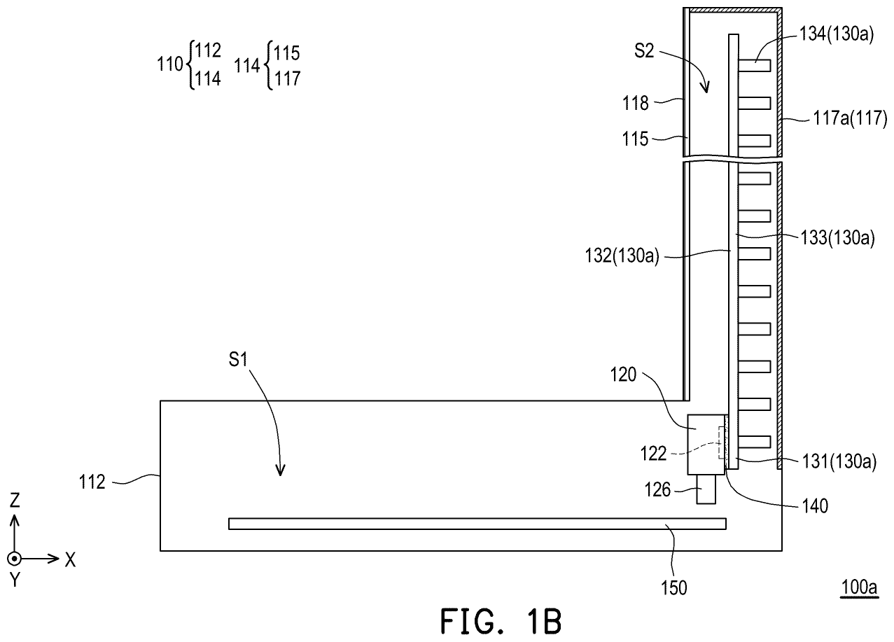

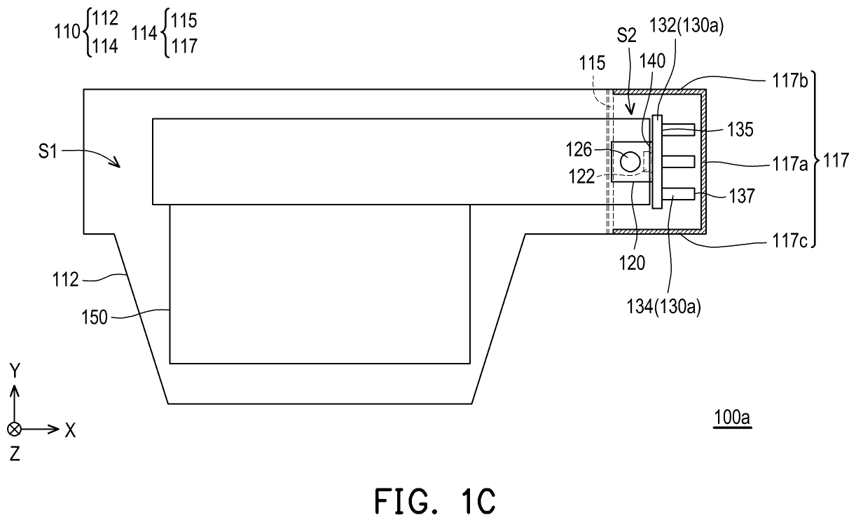

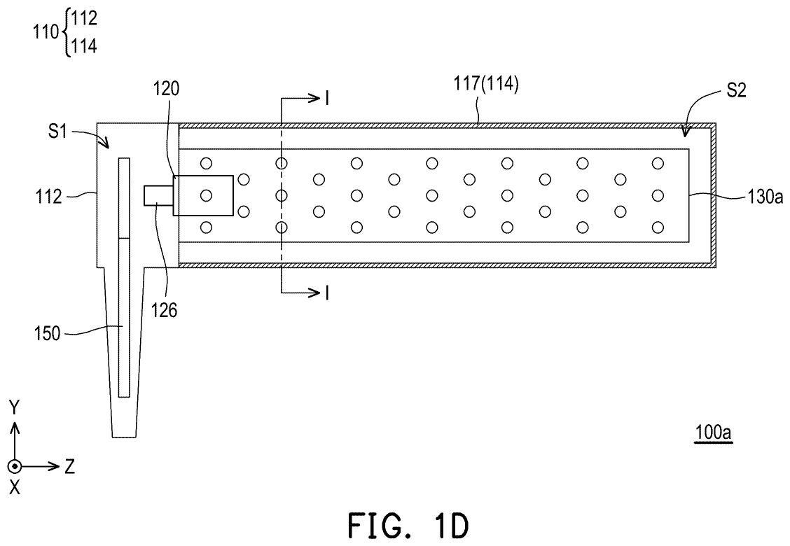

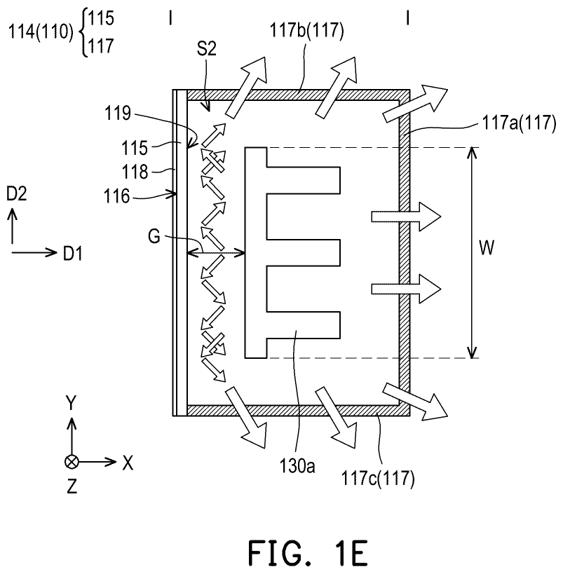

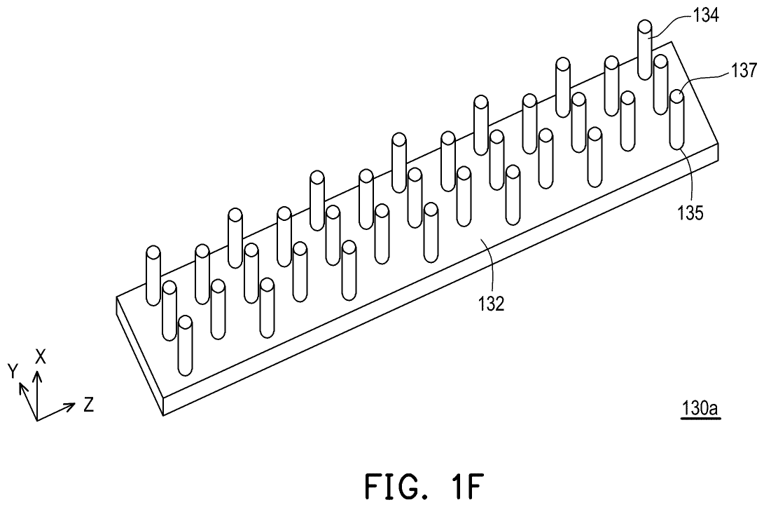

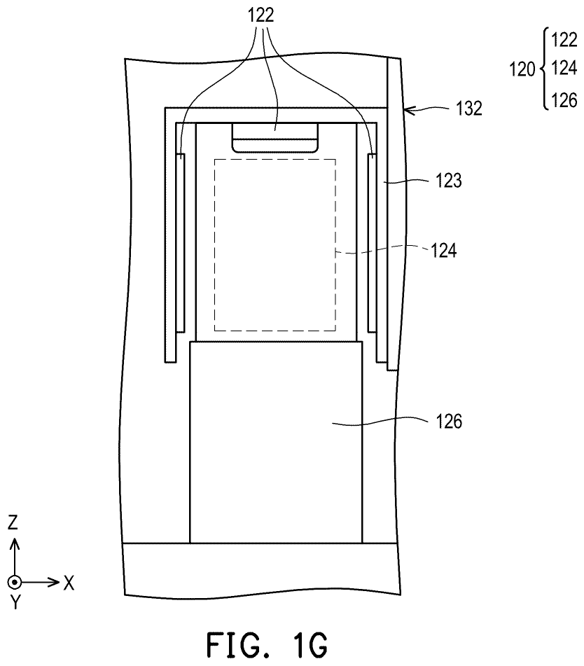

FIG. 1A is a three-dimensional schematic view of a head-mounted display device worn on a user according to an embodiment of the disclosure. FIG. 1B is a partial top perspective schematic view of the head-mounted display device of FIG. 1A. FIG. 1C is a partial front perspective schematic view of the head-mounted display device of FIG. 1A. FIG. 1D is a side perspective schematic view of the head-mounted display device of FIG. 1A. FIG. 1E is a cross-sectional schematic view along a line I-I of FIG. 1D. FIG. 1F is a three-dimensional schematic view of a heat dissipating module of FIG. 1D. FIG. 1G is a detailed schematic view of an optical engine module in FIG. 1D. It should be noted that the axial directions of the axes X, Y, and Z are drawn in each drawing, so that the viewing angle of each drawing can be clearly understood.

Please refer to FIG. 1A and FIG. 1B simultaneously. In the embodiment, a head-mounted display device 100a includes a housing 110, an optical engine module 120, and a heat dissipating module 130a. The housing 110 has a display portion 112 and a support portion 114. The display portion 112 has a first space S1, the support portion 114 has a second space S2, and the first space S1 and the second space S2 are communicated with each other. In other words, the first space S1 and the second space S2 are enclosed by walls of the housing. The support portion 114 of housing 110 has a side wall 115 and at least one heat dissipating wall 117, and the material of the at least one heat dissipating wall 117 is an infrared transmitting material and is different from the material of the side wall 115. The optical engine module 120 includes at least one heat source 122 and the optical engine module 120 is disposed in the first space S1. A part 131 of the heat dissipating module 130a is disposed in the first space S1 and is thermally connected to the at least one heat source 122. An other part 133 of the heat dissipating module 130a is disposed in the second space S2, wherein heat generated by the at least one heat source 122 of the optical engine module 120 located at the display portion 112 is capable of being transferred to the heat dissipating module 130a and then being transferred from the at least one heat dissipating wall 117 of the support portion 114 to the outside of the housing 110 by heat radiation.

Generally speaking, conduction, convection, and radiation are three ways to transfer heat, wherein radiation heat is also referred to as blackbody radiation. The blackbody radiation refers to electromagnetic radiation emitted by a blackbody in thermodynamic equilibrium. Infrared light is a type of electromagnetic radiation that has longer wavelengths than visible light. Infrared radiation with wavelengths ranging from 700 nanometers (nm) to 1 millimeter (mm) is often associated with heat because many objects emit infrared energy as a result of their temperature. Objects having a temperature above absolute zero all emit such radiation with a longer wavelength. In other words, the temperature of the object is the only variable that affects the wavelength of the radiation energy. In the case of forced convection, the proportion of radiation heat dissipation is relatively small, but in the case where the object is stationary and there is no external wind flow, the proportion of the radiation heat dissipation significantly increases.

The infrared transmitting material used for the at least one heat dissipating wall 117 of the embodiment refers to a material with an average transmittance characteristic of more than 70% in a mid-infrared wavelength band between 3 μm and 20 μm. In an embodiment, the infrared transmitting material is, for example, Teflon or poly(methyl methacrylate) (PMMA) plastic, but not limited thereto. The infrared light transmittance of the infrared transmitting material is greater than or equal to 70%, and an average transmittance of the infrared transmitting material in a visible light band is less than or equal to 5%, so as to prevent directly seeing the structure and elements inside the housing 110 corresponding to the infrared transmitting material used. In the case of normal natural convection or free convection, approximately 30% of the heat generated by the at least one heat source 122 is transferred to the outside of the housing 110 in the form of radiation heat, and since the at least one heat dissipating wall 117 of the embodiment may allow infrared light to pass through, the 30% of the radiation heat can be dissipated to the outside of the housing 110 almost without being absorbed by the housing 110, which can synchronously reduce the temperature of the housing 110, so that the surface temperature of the housing 110 comply with safety regulations (that is, below 48° C.).

In detail, please refer to FIG. 1B, FIG. 1C, and FIG. 1D simultaneously. In the embodiment, the at least one heat dissipating wall 117 of the support portion 114 of the housing 110 includes a first heat dissipating wall 117a disposed opposite to the side wall 115 of the support portion 114. The area of the first heat dissipating wall 117a is greater than the orthographic projection area of the heat dissipating module 130a on the first heat dissipating wall 117a, so as to allow most of the infrared radiation heat to be dissipated to the outside of the housing 110. As shown in FIG. 1A, the head-mounted display device 100a of the embodiment is, for example, smart glasses such as virtual reality (VR) glasses, augmented reality (AR) glasses, and extended reality (XR) glasses. The support portion 114 of the housing 110 is embodied as a temple, the side wall 115 of the support portion 114 is, for example, a wall of temple which is adapted to be in contact with a user U, and the at least one heat dissipating wall 117 of the support portion 114 is, for example, a wall of temple which is not in contact with the user U. In other words, the side wall 115 may include a contact surface that is in partial contact with a head portion of the user U, and the at least one heat dissipating wall 117 may be regarded as an exterior surface that is not in contact with the head portion of the user U.

More specifically, please refer to FIG. 1B, FIG. 1C, and FIG. 1D simultaneously. In the embodiment, the at least one heat dissipating wall 117 also includes a second heat dissipating wall 117b and a third heat dissipating wall 117c, wherein the second heat dissipating wall 117b and the third heat dissipating wall 117c are disposed opposite to each other. The second heat dissipating wall 117b respectively connects the side wall 115 and the first heat dissipating wall 117a. The third heat dissipating wall 117c respectively connects the side wall 115 and the first heat dissipating wall 117a. The side wall 115, the first heat dissipating wall 117a, the second heat dissipating wall 117b, and the third heat dissipating wall 117c define the second space S2. In other words, the second space S2 is enclosed by the side wall 115, the first heat dissipating wall 117a, the second heat dissipating wall 117b, and the third heat dissipating wall 117c. In addition to the side wall 115 close to the user U (please refer to FIG. 1A), at least one or all of the other exterior surfaces, that is, the first heat dissipating wall 117a, the second heat dissipating wall 117b, and the third heat dissipating wall 117c, are made of the infrared transmitting material. That is, the surfaces other than the contact surface in contact with the user U (please refer to FIG. 1A) may be made of the infrared transmitting material, so as to increase the radiation heat dissipation area. In an embodiment, the first heat dissipating wall 117a, the second heat dissipating wall 117b, and the third heat dissipating wall 117c may be directly injection molded from the infrared transmitting material, and then assembled with the side wall 115 to form the support portion 114 of the housing 110, but not limited thereto. In another embodiment, the at least one heat dissipating wall 117 of the support portion 114 may only include the first heat dissipating wall 117a, and the first heat dissipating wall 117a is, for example, a curved surface. The first heat dissipating wall 117a and the side wall 115 define the second space S2.

Please continue to refer to FIG. 1B, FIG. 1C, and FIG. 1D. The heat dissipating module 130a of the embodiment includes a heat dissipating plate 132 and a heat dissipating fin set 134, and the heat dissipating plate 132 is located between the at least one heat source 122 and the heat dissipating fin set 134. In the embodiment, the heat dissipating plate 132 is, for example, a flat-plate structure, and the heat dissipating plate 132 and the heat dissipating fin set 134 are an integrally formed structure, but not limited thereto. The heat dissipating module 130a extends from the first space S1 to be disposed in the second space S2 (the part 131 of the heat dissipating module 130a is accommodated in the first space S1 and the other part of the heat dissipating module 130a is accommodated in the second space S2), that is, the heat dissipating plate 132 extends from the first space S1 to the second space S2, the heat dissipating fin set 134 is disposed on the heat dissipating plate 132, and the heat dissipating module 130a may, for example, extend to an end of the support portion 114, so as to transfer the heat generated by the at least one heat source 122 from the display portion 112 to the support portion 114 for heat dissipation. The heat dissipating module 130a may be in thermal contact with the at least one heat source 122 through a thermal conductive material 140. In other words, the thermal conductive material 140 is disposed between the at least one heat source 122 and the heat dissipating plate 132. In an embodiment, the thermal conductive material 140 may be, for example, a thermal interface material (TIM), but not limited thereto. In other words, the heat dissipating module 130a is attached onto the at least one heat source 122 of the optical engine module 120 through the thermal conductive material 140, so as to transfer the heat generated by the at least one heat source 122 of the optical engine module 120 from the part of the heat dissipating module 130a in the first space S1 to the other part of the heat dissipating module 130a in the second space S2 for heat dissipation. In an embodiment, the material of the heat dissipating module 130a is, for example, a highly thermal conductive material, such as metal and graphite, wherein the metal is, for example, copper or aluminum, but not limited thereto. In an embodiment, the heat dissipating fin set 134 includes multiple heat dissipating fins. The heat dissipating plate 132 extends along a direction from the first space S1 to the second space S2. The multiple heat dissipating fins are arranged on the heat dissipating plate 132 and spaced apart from one another. Each of the multiple heat dissipating fins extends from the heat dissipating plate 132 toward the at least one heat dissipating wall 117.

In order to have improved heat dissipation, as shown in FIG. 1F, the heat dissipating module 130a may be, for example, a pin fin heatsink, the heat dissipating fin set 134 may be, for example, multiple pin fins, the multiple pin fins are disposed at intervals on the heat dissipating plate 132, each of the multiple pin fins has on end 135 which is thermally connected to the heat dissipating plate 132, and the other end 137 which is a free end and extends toward the first heat dissipating wall 117a (may refer to FIG. 1C and FIG. 1F). The pin fins may have sufficient surface area, and the radiation heat is emitted radially from the heat dissipating module 130a to the outside, such that the radiation heat radiated to the outside is not easily absorbed by itself, which can have an improved radiation heat dissipation efficiency. In the embodiment, the heat dissipating fin set 134 is not limited to the pin fins. The heat dissipating fin set 134 may also be multiple plate (multiple sheet) structures, as long as there is sufficient surface area for radiation heat dissipation, but not limited thereto. In addition, in an embodiment, the surface of the heat dissipating module 130a may also be subjected to a surface treatment to increase emissivity, such as a black treatment or a sandblasting surface treatment, but not limited thereto. In an embodiment, the heat dissipating module 130a may also be a heat pipe or a vapor chamber.

Next, please refer to FIG. 1B and FIG. 1E simultaneously. In the embodiment, in order to achieve good radiation heat dissipation, the side wall 115 of the support portion 114 may have a reflective surface 119 facing the first heat dissipating wall 117a and the contact surface 116 configured to contact with the user U. The reflective surface 119 faces the second space S2 and is located between the heat dissipating module 130a and the contact surface 116 of the side wall 115. In other words, the reflective surface 119 is not a contact surface, so the user U (please refer to FIG. 1A) can be prevented from being affected by the radiation heat due to skin contact. In an embodiment, the reflective surface 119 may be formed by subjecting the surface of the side wall 115 to a high reflectivity surface treatment, wherein the reflective surface 119 of the side wall 115 may be, for example, a surface of a white treated layer, a polished layer, or a mirror treated layer. In an embodiment, the area of the reflective surface 119 of the side wall 115 is greater than the orthographic projection area of the heat dissipating module 130a on the side wall 115, so as to effectively reflect the infrared radiation heat. In short, when the heat dissipating module 130a emits the infrared radiation heat (that is, arrow symbols in FIG. 1E), in addition to the at least one heat dissipating wall 117 that allows the infrared radiation heat to directly pass through to the outside of the housing 110, the infrared radiation heat reflected by the reflective surface 119 may also pass through the at least one heat dissipating wall 117 of the housing 110 to be dissipated to the outside.

Furthermore, please refer to FIG. 1E again. A distance G between the reflective surface 119 of the side wall 115 and the heat dissipating module 130a in a first direction D1 (parallel to the X axis) is greater than or equal to ¼ of a width W of the heat dissipating module 130a along a second direction D2 (parallel to the Y axis), that is, G≥¼ W or G≥0.25 W, and furthermore, the distance G is the distance between the reflective surface 119 and the heat dissipating plate of the heat dissipating module 130a in the first direction D1, wherein the first direction D1 and the second direction D2 are perpendicular to each other, which can ensure that more than half of the radiation heat may be dissipated to the outside through the at least one heat dissipating wall 117 made of the infrared transmitting material after reflection. If the distance G between the reflective surface 119 of the side wall 115 and the heat dissipating module 130a in the first direction D1 is less than ¼ of the width W of the heat dissipating module 130a along the second direction D2, that is, G<¼ W or G<0.25 W, most of the radiation heat will return to the surface of the heat dissipating module 130a and be absorbed after reflection. In other words, the reflective surface 119 of the embodiment is not in contact with the heat dissipating module 130a and maintains a specific distance from the heat dissipating module 130a, so that the infrared radiation heat transmitted to the reflective surface 119 can be effectively reflected to the outside of the housing 110 without being absorbed by the heat dissipating module 130a. In addition, in the embodiment, a thermal insulation material layer 118 may be partially or entirely disposed on the contact surface 116 (outer surface) of the side wall 115 for preventing from transmitting the radiation heat to the user U, wherein the thermal insulation material layer 118 is, for example, rubber to insulate heat energy.

Next, please refer to FIG. 1A, FIG. 1B, and FIG. 1G simultaneously. In the embodiment, the at least one heat source 122 of the optical engine module 120 is, for example, at least one display panel, which is adapted to emit an image beam. The optical engine module 120 also includes a light guiding module 124 and a lens module 126. The light guiding module 124 is disposed on a transmission path of the image beam to guide the image beam to the lens module 126. The lens module 126 receives the image beam from the light guiding module 124 and projects the image beam toward the display portion 112 of the housing 110. Specifically, the at least one display panel is three display panels, and the three display panels are, for example, disposed on a thermal conductive plate 123 and then thermally connected to the heat dissipating module 130a. FIG. 1G does not further illustrate the heat dissipating module 130a. FIG. 1G only illustrates the heat transfer manners of the three display panels. There is no limitation on the configuration of the three display panels, as long as heat of the three display panels can be transferred to the heat dissipating module 130a, the same belongs to the implementation to be protected in the disclosure and is not limited to the implementation of FIG. 1G. Each display panel (heat source) may be, for example, a liquid crystal display panel, an organic light emitting diode (LED) display panel, a mini LED display panel, or a micro LED display panel, and the light guiding module 124 may be, for example, an X-Cube, but the disclosure is not limited thereto. In addition, the head-mounted display device 100a of the embodiment also includes at least one display element (two display elements 150 are schematically shown), wherein the at least one display element 150 is disposed on the display portion 112 to receive the image beam from the lens module 126 and guide the image beam to the user U.

In an embodiment, the head-mounted display device 100a may be, for example, a see-through head-mounted display, but not limited thereto. In an embodiment not shown, the head-mounted display device may also include a control module (not shown) electrically connected to the optical engine module 120, so that the image beam generated by the optical engine module 120 is projected to the at least one display element 150 disposed on the display portion 112. Each of the at least one display elements 150 may be transparent or translucent allowing the user wearing the head-mounted display device 100a, 100b to look through the at least one display element 150 to see the real world and displaying visual artificial reality content corresponding the image beam to the user at the same time. In an embodiment not shown, the head-mounted display device may also include an optical waveguide to receive the image beam from the optical engine module 120, and the image beam may be uninterruptedly reflected in the optical waveguide and then projected to the at least one display element 150. In an embodiment not shown, the at least one of the display element 150 of the head-mounted display device may be an optical waveguide which is configured to receive the image beam from the lens module 126 of the optical engine module 120 and guide the image beam to the user U, wherein the optical waveguide is known to persons skilled in the art and will not be described again. The head-mounted display device is worn on the user to provide the user with an augmented reality (AR) or virtual reality (VR) image experience.

It should be further explained that the optical engine module 120 and the heat dissipating module 130a of the embodiment are only drawn on one side of the head-mounted display device. However, in practical applications, the head-mounted display device includes two optical engine modules 120 and two heat dissipating modules 130a. One of the two optical engine modules 120 and one of the two heat dissipating modules 130a may be disposed on the left side of the head-mounted display device, and the other one of the two optical engine modules 120 and the other one of the two heat dissipating modules 130a may be disposed on the right side of the head-mounted display device, that is, two sides of the display portion 112 are respectively provided with one optical engine modules 120, two of the support portion 114 are respectively provided with one heat dissipating modules 130a, and at least part of the corresponding heat dissipating module 130a is accommodated in the first space of the display portion 112. Therefore, the optical engine module 120 and the heat dissipating module 130a disposed on the other side of the housing 110 of the head-mounted display device will not be described again.

Since a part of the housing 110 of the embodiment is made of the infrared transmitting material that does not absorb infrared light, the heat generated by the heat source 122 may be transmitted to the heat dissipating module 130a. The radiation heat emitted from the heat dissipating module 130a is transmitted to the at least one heat dissipating wall 117, and then is transferred to the outside of the housing 110, that is, the radiation heat may directly pass through the part of the housing 110 to be dissipated to the outside of the housing 110, so as to increase the radiation heat dissipation area. The housing 110 itself may also have heat dissipation ability of conduction, convection, and radiation, wherein the infrared transmitting material is further adopted in the at least one heat dissipating wall 117 of the support portion 114, which can prevent the part of the housing 110 from being heated by the radiation heat of the heat source 122 in addition to increasing the radiation heat dissipation area, while enabling the surface temperature of the housing 110 to comply with safety regulations (that is, below 48° C.). In short, in the embodiment, the radiation heat dissipation area is increased through the at least one heat dissipating wall 117 made of the infrared transmitting material, so that the head-mounted display device 100a of the embodiment can have improved heat dissipation and display quality.

Other embodiments will be listed below for illustration. It must be noted here that the following embodiments continue to use the reference numerals and some content of the foregoing embodiments, wherein the same numerals are adopted to represent the same or similar elements, and the description of the same technical content is omitted. For the description of the omitted part, reference may be made to the foregoing embodiments and will not be repeated in the following embodiments.

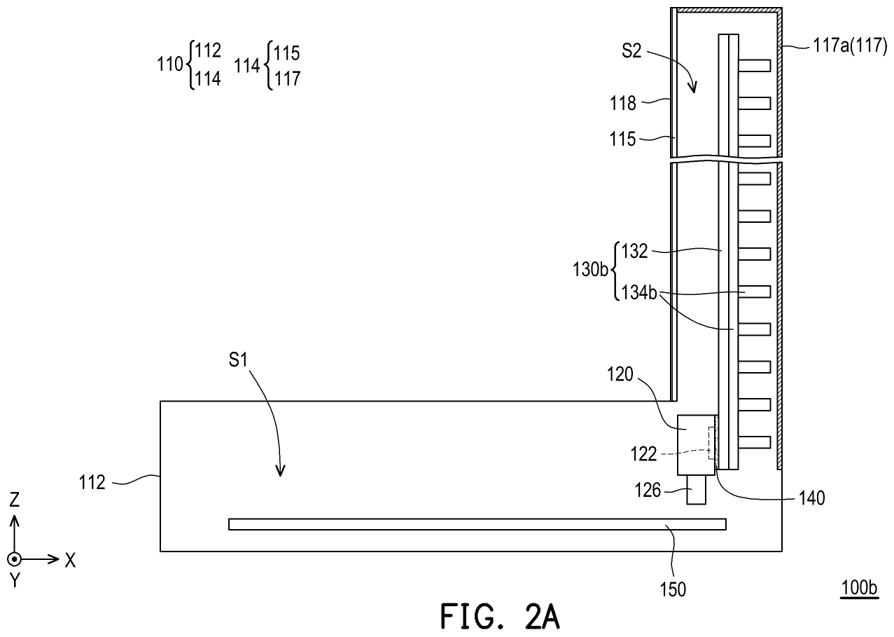

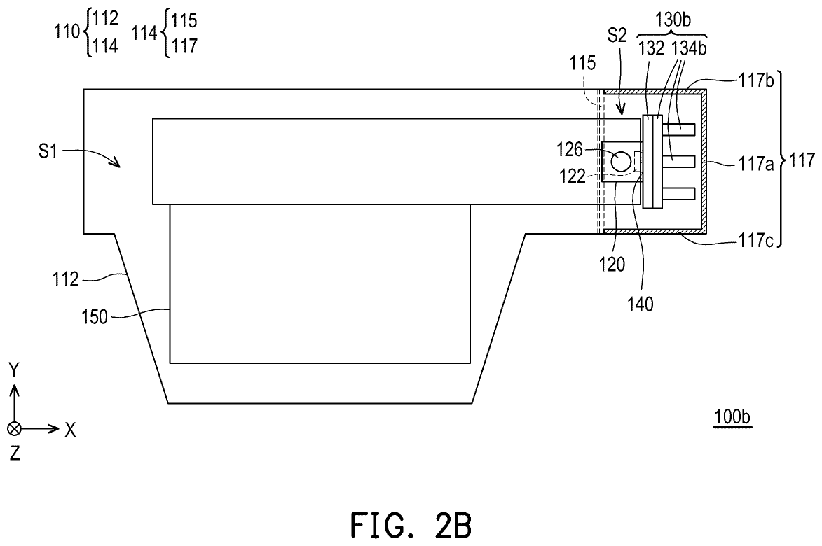

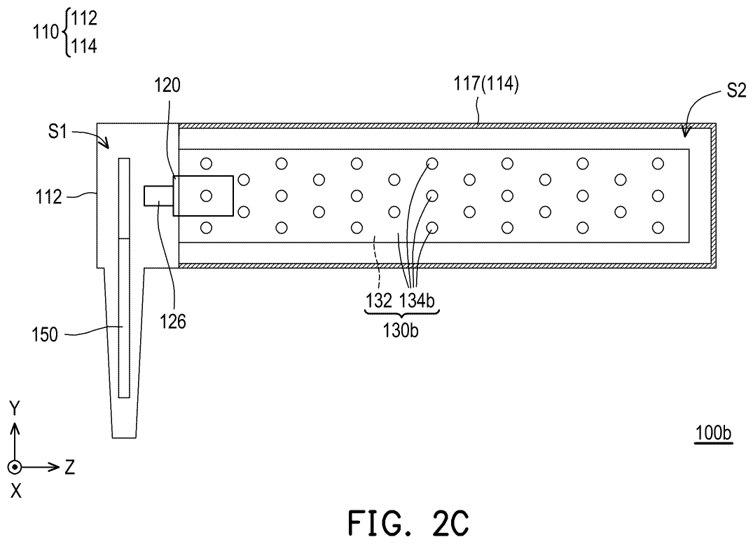

FIG. 2A is a partial top perspective schematic view of a head-mounted display device according to another embodiment of the disclosure. FIG. 2B is a partial front perspective schematic view of the head-mounted display device of FIG. 2A. FIG. 2C is a side perspective schematic view of the head-mounted display device of FIG. 2A. Please refer to FIG. 1B, FIG. 1C, FIG. 1D, FIG. 2A, FIG. 2B, and FIG. 2C. A head-mounted display device 100b of the embodiment is similar to the head-mounted display device 100a. The main difference between the two embodiments is that a heat dissipating module 130b of the embodiment is different from the heat dissipating module 130a.

In the embodiment, the material of the heat dissipating plate 132 of the heat dissipating module 130b is different from the material of a heat dissipating fin set 134b. In an embodiment, the material of the heat dissipating plate 132 is a highly thermal conductive material, such as metal and graphite, wherein the metal is, for example, copper or aluminum, but not limited thereto. In an embodiment, the material of the heat dissipating fin set 134b is, for example, an infrared radiation material, wherein the infrared radiation material is, for example, ceramics or tourmaline. In other embodiments, the heat dissipating fin set 134b includes, for example, a heat dissipating plate portion and multiple heat dissipating fins. The multiple heat dissipating fins are arranged on the heat dissipating plate portion and spaced apart from one another. Each of the multiple heat dissipating fins extends from the heat dissipating plate portion toward the at least one heat dissipating wall 117. The heat dissipating plate portion of the heat dissipating fin set 134b is thermally connected to the heat dissipating plate 132. The heat dissipating plate portion and the multiple heat dissipating fins are all made of the infrared radiation material. In other words, the infrared radiation material may be, for example, made into the shape of the heat dissipating fin set 134b of the embodiment to be assembled on the heat dissipating plate 132, but not limited thereto. In an embodiment, the orthographic projection area of the heat dissipating fin set 134b on the heat dissipating plate 132 overlaps with the area of the heat dissipating plate 132.

In summary, the embodiments of the disclosure have at least one of the following advantages or effects. In the design of the head-mounted display device of the disclosure, the material of the heat dissipating wall of the support portion is the infrared transmitting material and is different from the material of the side wall of the support portion, wherein the heat generated by the heat source is transferred to the heat dissipating module and is transferred from the heat dissipating wall to the outside of the housing by radiation, so as to increase the radiation heat dissipation area, so that the head-mounted display device of the disclosure has improved heat dissipation and display quality.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the disclosure” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the disclosure as defined by the following claims. Moreover, no element and component in the present disclosure is intended to be dedicated to the public regardless of whether the element or component is explicitly recited in the following claims.

What is claimed is:

1. A head-mounted display device, comprising a housing, an optical engine module, and a heat dissipating module, wherein:
the housing has a display portion and a support portion, the display portion has a first space, the support portion has a second space, and the first space and the second space are communicated, wherein the support portion has a side wall and at least one heat dissipating wall, and a material of the at least one heat dissipating wall is an infrared transmitting material and is different from a material of the side wall;
the optical engine module comprises at least one heat source and is disposed in the first space;
a part of the heat dissipating module is disposed in the first space and is connected to the at least one heat source, and an other part of the heat dissipating module is disposed in the second space, wherein heat generated by the at least one heat source is transferred to the heat dissipating module and is transferred from the at least one heat dissipating wall to an outside of the housing by radiation.

2. The head-mounted display device according to claim 1, wherein the at least one heat dissipating wall of the support portion comprises a first heat dissipating wall disposed opposite to the side wall, and an area of the first heat dissipating wall is greater than an orthographic projection area of the heat dissipating module on the first heat dissipating wall.

3. The head-mounted display device according to claim 2, wherein the support portion is a temple, the side wall is adapted to be in contact with a user, and the at least one heat dissipating wall is not in contact with the user.

4. The head-mounted display device according to claim 2, wherein the at least one heat dissipating wall further comprises a second heat dissipating wall and a third heat dissipating wall, wherein the second heat dissipating wall and the third heat dissipating wall are disposed opposite to each other, the second heat dissipating wall connects the side wall and the first heat dissipating wall, the third heat dissipating wall connects the side wall and the first heat dissipating wall, and the side wall, the first heat dissipating wall, the second heat dissipating wall, and the third heat dissipating wall define the second space.

5. The head-mounted display device according to claim 2, wherein the heat dissipating module comprises a heat dissipating plate and a heat dissipating fin set, and the heat dissipating plate is located between the at least one heat source and the heat dissipating fin set.

6. The head-mounted display device according to claim 5, further comprising:
a thermal conductive material, disposed between the at least one heat source and the heat dissipating plate.

7. The head-mounted display device according to claim 5, wherein the heat dissipating fin set is a plurality of pin fins, one end of each of the pin fins is connected to the heat dissipating plate, and other end extends toward the first heat dissipating wall.

8. The head-mounted display device according to claim 5, wherein a material of the heat dissipating plate is different from a material of the heat dissipating fin set.

9. The head-mounted display device according to claim 8, wherein the material of the heat dissipating fin set comprises an infrared radiation material.

10. The head-mounted display device according to claim 9, wherein the infrared radiation material comprises ceramics or tourmaline.

11. The head-mounted display device according to claim 5, wherein an orthographic projection area of the heat dissipating fin set on the heat dissipating plate overlaps with an area of the heat dissipating plate.

12. The head-mounted display device according to claim 1, wherein the side wall of the support portion has a reflective surface, and the reflective surface faces the second space and is located between the heat dissipating module and an outer surface of the side wall.

13. The head-mounted display device according to claim 12, wherein the reflective surface of the side wall comprises a white treated layer, a polished layer, or a mirror treated layer.

14. The head-mounted display device according to claim 12, wherein an area of the reflective surface of the side wall is greater than an orthographic projection area of the heat dissipating module on the reflective surface.

15. The head-mounted display device according to claim 12, wherein a distance between the reflective surface of the side wall and the heat dissipating module in a first direction is greater than or equal to ¼ of a width of the heat dissipating module along a second direction, wherein the first direction and the second direction are perpendicular to each other.

16. The head-mounted display device according to claim 12, wherein the outer surface of the side wall has a thermal insulation material layer.

17. The head-mounted display device according to claim 1, wherein the infrared transmitting material comprises Teflon or poly(methyl methacrylate) plastic.

18. The head-mounted display device according to claim 1, wherein an infrared transmittance of the infrared transmitting material is greater than or equal to 70%, and an average transmittance of light beams in a visible light band is less than or equal to 5%.

19. The head-mounted display device according to claim 1, wherein the at least one heat source is at least one display panel, the at least one display panel is adapted to emit an image beam, and the optical engine module further comprises a light guiding module and a lens module, wherein:
the light guiding module is disposed on a transmission path of the image beam to guide the image beam to the lens module; and
the lens module receives the image beam from the light guiding module and projects the image beam toward the display portion.

20. The head-mounted display device according to claim 19, further comprising:
at least one display element, disposed on the display portion of the housing to receive the image beam from the lens module and guide the image beam to a user wearing the head-mounted display device.
